(19) United States
(12) Patent Application Publication
(10) Pub. No.: US 2025/0118572 A1
(43) Pub. Date: Apr. 10, 2025

(54) ANNEAL CHAMBER

(71) Applicant: Applied Materials, Inc., Santa Clara, CA (US)

(72) Inventors: Paul R. McHugh, Kalispell, MT (US); Gregory J. Wilson, Kalispell, MT (US); Nolan L. Zimmerman, Kalispell, MT (US); Deepak Saagar Kalaikadal, Kalispell, MT (US); Matthew Paul McHugh, Kalispell, MT (US); Daniil Oliferovskiy, Kalispell, MT (US)

(73) Assignee: Applied Materials, Inc., Santa Clara, CA (US)

(21) Appl. No.: 18/483,994

(22) Filed: Oct. 10, 2023

(51) Int. Cl. H01L 21/324; H01L 21/67; H01L 21/68; H01L 21/687

(52) U.S. Cl. CPC H01L 21/324; H01L 21/67161; H01L 21/68; H01L 21/6875; H01L 21/68785; H01L 2221/6835

(57) ABSTRACT

Exemplary anneal chambers may include a base that defines a chamber interior. The base may include a cooling plate within the chamber interior. The base and the cooling plate may be integral with one another. The chambers may include a lid that is coupled with the base. The chambers may include a heater plate mounted in the chamber interior alongside the cooling plate. The chambers may include a transfer hoop movably coupled within the chamber interior. The base may define a first transfer hoop recess about at least a portion of the heater plate. The base may define a second transfer hoop recess about at least a portion of the cooling plate.

### TECHNICAL FIELD

The present technology relates to methods, components, and apparatuses for semiconductor manufacturing. More specifically, the present technology relates to annealing chambers for semiconductor manufacturing.

### BACKGROUND

Microelectronic devices, such as semiconductor devices, are fabricated on and/or in wafers or workpieces. As critical dimensions for features formed on the semiconductor devices continue shrinking, the number of steps needed to pattern small structures is increasing, thus creating the need for treatments of multiple patterning layers. In the case of silicon wafers, annealing is often used to improve the surface roughness and crystal quality of the wafer. Annealing may also be used to remove defects and impurities from the surface of the wafer. Annealing may be used to change the material properties of the layers on the substrate. It may also be used to activate dopants, drive dopants between films on the substrate, change film-to-film or film-to-substrate interfaces, density deposited films, or to repair damage from ion implantation. Many aspects of an annealing process may impact process uniformity, such as non-uniform temperature distribution across a wafer, uneven gas flow paths, as well as other process and component parameters. Even minor discrepancies across a substrate may impact downline finishing processes.

Thus, there is a need for improved systems and methods that can be used to produce high quality devices and structures. These and other needs are addressed by the present technology.

### SUMMARY

Exemplary anneal chambers may include a base that defines a chamber interior. The base may include a cooling plate within the chamber interior. The base and the cooling plate may be integral with one another. The chambers may include a lid that is coupled with the base. The chambers may include a heater plate mounted in the chamber interior alongside the cooling plate. The chambers may include a transfer hoop movably coupled within the chamber interior. The base may define a first transfer hoop recess about at least a portion of the heater plate. The base may define a second transfer hoop recess about at least a portion of the cooling plate.

In some embodiments, the base may include a heat shield that extends between the heater plate and the first transfer hoop. The transfer hoop may include a plurality of substrate-engaging fingers. The heater plate may define a plurality of recesses that extend partially through a thickness of the heater plate. Each of the plurality of recesses may be aligned with a respective one of the plurality of substrate-engaging fingers. The transfer hoop may include a plurality of substrate-engaging fingers. The cooling plate may define a plurality of recesses that extend partially through a thickness of the cooling plate. Each of the plurality of recesses may be aligned with a respective one of the plurality of substrate-engaging fingers. The lid may define a first plurality of gas distribution apertures positioned above the heater plate. The lid may define a second plurality of gas distribution apertures positioned above the cooling plate. The lid may define a third plurality of gas distribution apertures in a region disposed between the heater plate and the cooling plate. The first plurality of gas distribution apertures may be arranged in a first plurality of concentric rings. The second plurality of gas distribution apertures may be arranged in a second plurality of concentric rings. The third plurality of gas distribution apertures may be arranged in a plurality of concentric arcs. The first plurality of concentric rings, the second plurality of concentric rings, and the plurality of concentric arcs may each have different center points. Each of the heater plate and the cooling plate may define a single backside gas port.

Some embodiments of the present technology may encompass anneal chambers that may include a base that defines a chamber interior. The base may include a cooling plate within the chamber interior. The base and the cooling plate may be integral with one another. The chambers may include a lid that is coupled with the base. The chambers may include a heater plate mounted in the chamber interior alongside the cooling plate. The heater plate may include multiple heating zones. The chambers may include a transfer hoop movably coupled within the chamber interior. The base may define a first transfer hoop recess about at least a portion of the heater plate. The base may define a second transfer hoop recess about at least a portion of the cooling plate.

In some embodiments, each of the heater plate and the cooling plate may define a plurality of standoffs that are configured to support a substrate at a position that is elevated relative to a top surface of the respective plate. A height of the plurality of standoffs may be adjustable relative to the top surface of the respective plate. The base may define one or more exhaust ports that are disposed beneath the heater plate. The lid may include an anodized inner surface. The transfer hoop may include a plurality of substrate-engaging fingers. Each of the substrate-engaging fingers may include an upward facing protrusion that is positioned to center a substrate within the transfer hoop. Each of the plurality of substrate-engaging fingers may include opaque quartz.

Some embodiments of the present technology may encompass anneal chambers that may include a base that defines a chamber interior. The base may include a cooling plate within the chamber interior. The base and the cooling plate may be integral with one another. The chambers may include a heater plate mounted in the chamber interior alongside the cooling plate. The chambers may include a lid that is coupled with the base. The lid may define a plurality of gas distribution apertures that extend over the heater plate and the cooling plate. The chambers may include a transfer hoop movably coupled within the chamber interior.

In some embodiments, the base may define a transfer port proximate the cooling plate. The base may include a heat shield that extends between the heater plate and the transfer hoop. The transfer hoop may include a plurality of substrate-engaging fingers. The heat shield may define a plurality of slits that enable the plurality of substrate-engaging fingers to protrude radially inward of the heat shield. The heating plate may include a circular heating zone and an annular heating zone that is disposed radially outward of the circular heating zone. The circular heating zone and the annular heating zone may be independently controllable.

Such technology may provide numerous benefits over conventional systems and techniques. For example, embodiments of the present technology may improve the temperature uniformity across the substrate. In particular, temperature uniformity may be improved by improving heating elements and better isolating cool components from heated components. Additionally, embodiments of the present invention may improve gas flow uniformity across the chamber. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 illustrates a schematic top plan view of an exemplary annealing chamber according to some embodiments of the present technology.

FIG. 2 illustrates a partial cross-sectional side view of the annealing chamber of FIG. 1.

FIG. 3 illustrates a partial cross-sectional side view of the annealing chamber of FIG. 1.

FIG. 4 illustrates a partial cross-sectional side view of the annealing chamber of FIG. 1.

FIG. 5 illustrates a partial isometric view of the annealing chamber of FIG. 1.

FIG. 6 illustrates a bottom perspective view of a lid of the annealing chamber of FIG. 1.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

In many or most annealing applications, it is important that the film layers on a substrate have a uniform thickness across the substrate or workpiece. Non-uniformities can be caused by temperature non-uniformity during annealing operations, and/or irregular distribution of gas flow. Conventional anneal chambers use heater designs that have edge notches through which transfer hoop fingers pass through. These notches create temperature uniformity issues. Additionally, the aluminum fingers of the transfer hoop remain close to wafer during heating, which may cause further temperature uniformity issues. Cold plates in conventional chambers are formed as separate components from the chamber base, which limits thermal mass and thermal conduction and may contribute to temperature uniformity issues. Additionally, gases delivered above heater may flow throughout the chambers and may cool the substrate at the heater and may heat the substrate at the cold plate, which may result in process irregularities.

The present technology overcomes these challenges by improving temperature uniformity by replacing notches in heater edge with shallow recesses, changing the transfer hoop geometry, position, and finger material, and utilizing a new heater. Unwanted heating of the transfer hoop may be lessened by adding a heat shield that surrounds the substrate, along with other chamber modifications to improve the cooling of the transfer hoop. Embodiments may improve substrate cooldown performance by replacing a separate cold plate with a monolithic cold plate that is integrated into the cooled base chamber and by replacing the helium manifold with a center delivery. Gas delivery and exhaust may also be improved. Accordingly, the present technology may improve the quality of substrates produced by annealing operations.

Although the remaining disclosure will routinely identify specific annealing processes utilizing the disclosed technology, it will be readily understood that the systems and methods are equally applicable to other annealing chambers and systems, as well as processes as may occur in the described systems. Accordingly, the technology should not be considered to be so limited as for use with these specific annealing processes or systems alone. The disclosure will discuss one possible system that may include annealing components according to embodiments of the present technology before additional variations and adjustments to this system according to embodiments of the present technology are described.

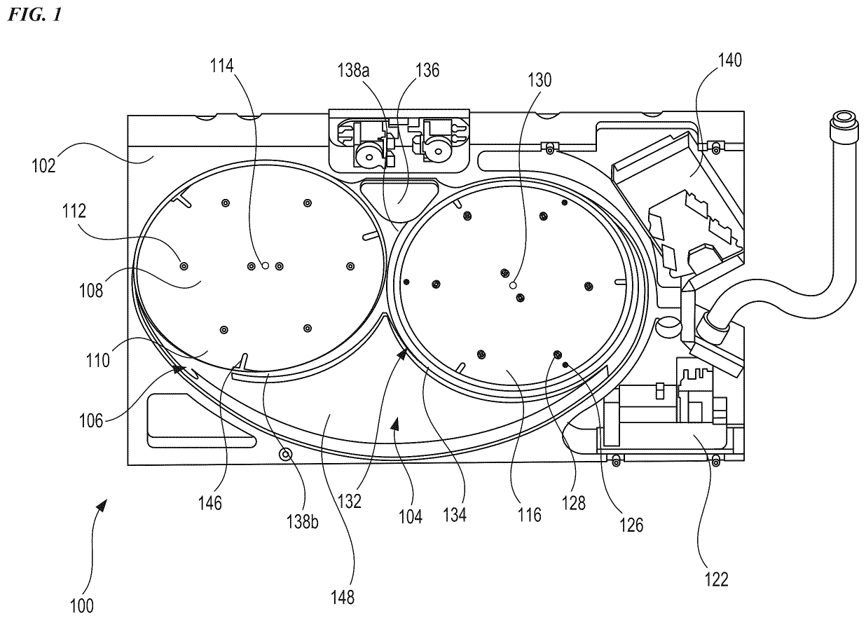

FIG. 1 illustrates a schematic view of an exemplary anneal chamber 100 in accordance with the present invention. Anneal chamber 100 may be used to perform annealing operations. For example, a substrate may be positioned within anneal chamber 100, which may then be purged of oxygen. The substrate may be heated for a period of time and then cooled down quickly before being removed from anneal chamber 100. In some embodiments, upon entering anneal chamber 100, a substrate may be positioned on or above a cooling plate during the purge process, rather than being positioned on or above a heater plate. This may prevent the substrate from being exposed to the higher temperatures of the heating place in an oxygenated environment. Once anneal chamber 100 is fully purged, the substrate may be moved to the heating plate to begin the annealing process.

Anneal chamber 100 may include a base 102, which may define a chamber interior 104. Substrates may be positioned within chamber interior 104 during annealing operations. For example, base 102 may define a transfer port 106 that provides access for an end effector of transfer apparatus to transfer substrates to and from chamber interior 104. Transfer port 106 may include a valve (such as a slit valve), door, or other mechanism (not shown) that may selectively close transfer port 106. Transfer port 106 may be disposed proximate a cooling plate 108 in some embodiments. Cooling plate 108 may be formed within chamber interior 104 and may be formed integrally with base 102 as a single monolithic component in some embodiments. By forming cooling plate 108 and base 102 integrally, a thermal mass of cooling plate 108 is significantly increased over existing designs, which may greatly improve the ability to quickly cool substrates after the heating process.

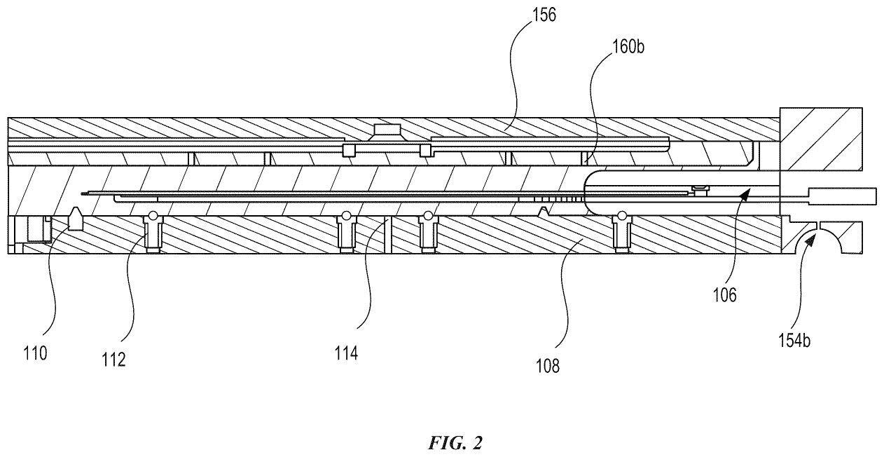

Cooling plate 108 may include one or more lead ins 110 that may help center a substrate with respect to cooling plate 108 as best shown in FIG. 2. For example, each lead in 110 may be positioned such that the respective lead in 110 protrudes upward from the surface of cooling plate 108 just outside (e.g., less than 2 mm, less than 1 mm, less than 0.5 mm, less than 0.25 mm, less than 0.1 mm, or less) of an outer periphery of a substrate centered on cooling plate 108. For example, if the substrate has a diameter of 300 mm, each lead in 110 may be positioned at between or about 150 mm and 152 mm from a center of cooling plate 108. Such positioning may help ensure that a substrate positioned above cooling plate 108 may be centered with respect to cooling plate 108, as the substrate may be maintained radially inward of lead ins 110 with lead ins 110 being in contact and/or close proximity with a peripheral edge of the substrate to prevent the substrate from laterally shifting relative to cooling plate 108. While shown with three lead ins 110, it will be appreciated that greater numbers of lead ins 110 may be used in various embodiments. For example, cooling plate 108 may include at least three lead ins, at least four lead ins, at least five lead ins, at least six lead ins, at least 10 lead ins, at least 20 lead ins, or more. Lead ins 110 may be positioned at regular or irregular intervals about cooling plate 108. In some embodiments, each lead in 110 may be formed from or otherwise include a ceramic or other dielectric material. In a particular embodiment, each lead in 110 may be formed from other otherwise include silicon nitride.

Cooling plate 108 may include one or more standoffs 112 that may elevate a substrate above a top surface of cooling plate 108. For example, each standoff 112 may be positioned at a position in which the respective standoff 112 protrudes upward from the surface of cooling plate 108 radially inward of an outer periphery of a substrate centered on cooling plate 108. For example, if the substrate has a diameter of 300 mm, each standoff 112 may be positioned within 150 mm of a center of cooling plate 108. In some embodiments, each standoff 112 may be at a same radial distance from a center of cooling plate 108, while in other embodiments one or more standoffs 112 may be at different radial positions. For example, as illustrated, cooling plate 108 includes an annular array of standoffs 112 at one radial position and two additional standoffs 112 on opposing sides of a center of cooling plate 108 at a second, more inward radial position. It will be appreciated that any arrangement of three or more standoffs 112 may be utilized that stably supports a substrate above cooling plate 108. While shown with eight standoffs 112, it will be appreciated that other numbers of standoffs 112 may be used in various embodiments. For example, cooling plate 108 may include at least three standoffs, at least four standoffs, at least five standoffs, at least six standoffs, at least 10 standoffs, at least 20 standoffs, or more. Standoffs 112 may be positioned at regular or irregular intervals about cooling plate 108. In some embodiments, each standoff 112 may protrude above cooling plate 108 by a smaller distance than each lead in 110, which may enable lead ins 110 to center a substrate with respect to cooling plate 108 even when the substrate is seated atop standoffs 112. In some embodiments, a height or protrusion distance of each standoff 112 may be adjustable. For example, each standoff 112 may be coupled with an actuator (not shown) that may be used to raise and lower standoffs 112 with respect to cooling plate 108. The actuator may include a shoulder bolt that includes standoff 112 on a top end of the shoulder bolt. Shims may be positioned under the shoulder bolt to adjust the protrusion height of standoff 112. In some embodiments, the actuator may include a motorized linear actuator that may control a protrusion height of standoff 112. In some embodiments, each standoff 112 may be formed from a crystalline material, such as sapphire, although other materials (including electrically conductive materials) are possible in various embodiments.

Cooling plate 108 may define one or more backside gas ports 114. Each backside gas port 114 may be fluidly coupled with at least one gas source, which may be used to flow a gas to a backside of the substrate. For example, an inert gas, such as helium, may be flowed to the backside of the substrate through backside gas ports 114 to help thermally couple the substrate with cooling plate 108. Any number of backside gas ports 114 may be included on cooling plate 108. For example, cooling plate 108 may include one or more backside gas ports, two or more backside gas ports, three or more backside gas ports, four or more backside gas ports, five or more backside gas ports, six or more backside gas ports, or more. Backside gas ports 114 may be disposed at any location and in any arrangement on cooling plate 108. In a particular embodiment, cooling plate 108 may define a single backside gas port 114, which may be centered or approximately centered (e.g., within an inner 15% of cooling plate 108, within an inner 10% of cooling plate 108, within an inner 5% of cooling plate 108, within an inner 1% of cooling plate 108, etc.) on cooling plate 108. The use of a single, centrally location backside gas port 114 may reduce the purge time of backside gas ports 114 and may simplify the design of cooling plate 108.

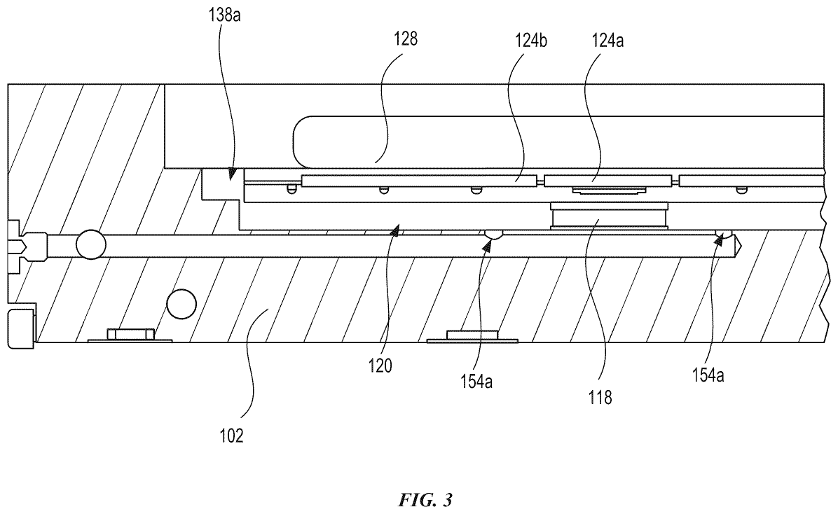

Chamber 100 may include a heater plate 116 that is mounted in chamber interior 104. For example, heater plate 116 may be positioned alongside cooling plate 108 in some embodiments. Heater plate 116 may be sized and shaped to receive a substrate. For example, in some embodiments heater plate 116 may be circular. Heater plate 116 may be separately formed from base 102 and cooling plate 108. For example, heater plate 116 may be supported by a stem 118 that is mounted within base 102, such as illustrated in FIG. 3. Stem 118 may support heater plate 116 above base 102 such that no portion of base 102 is in contact with heater plate 116, which may help thermally isolate the two components. For example, base 102 may define a recess 120 that is sized and shaped to be slightly larger than heater plate 116 and/or stem 118 such that a top surface of heater plate 116 may be substantially coplanar with a top surface of cooling plate 108.

Heater plate 116 may be designed to heat a substrate during annealing operations and may include one or more embedded heating elements. For example, heater plate 116 may include one or more resistive heating elements, such as heating coils, that are disposed within heater plate 116 and coupled with a heater controller 122 (which, for example, may be coupled with base 102 at a position outward of chamber interior 104) via one or more wires or rods that extend through stem 118. In some embodiments heater plate 116 may include a single heating element that heats substantially all of heater plate 116 in a generally uniform manner. In other embodiments, heater plate 116 may include multiple heating elements that divide heater plate 116 into multiple independently controllable zones. For example, in the illustrated embodiment heater plate 116 includes an inner heating element 124a forming a first zone and an outer heating element 124b forming a second zone. Inner heating element 124a may heat a circular inner zone and outer heating element 124b may heat an annular outer zone that is disposed radially outward of the circular heating zone. It will be appreciated that any number of heating elements and heating zones may be provided in any arrangement. For example, a number of concentric heater zones may be used in some embodiments. In other embodiments, wedge-shaped and/or arc-shaped heater zones may be utilized instead or, or in conjunction with, concentric heater zones.

Turning back to FIG. 1, heater plate 116 may include one or more lead ins 126 that may help center a substrate with respect to heater plate 116. For example, each lead in 126 may be positioned such that the respective lead in 126 protrudes upward from the surface of heater plate 116 just outside (e.g., less than 2 mm, less than 1 mm, less than 0.5 mm, less than 0.25 mm, less than 0.1 mm, or less) of an outer periphery of a substrate centered on heater plate 116. For example, if the substrate has a diameter of 300 mm, each lead in 126 may be positioned at between or about 150 mm and 152 mm from a center of heater plate 116. Such positioning may help ensure that a substrate positioned above heater plate 116 may be centered with respect to heater plate 116, as the substrate may be maintained radially inward of lead ins 126 with lead ins 126 being in contact and/or close proximity with a peripheral edge of the substrate to prevent the substrate from laterally shifting relative to heater plate 116. While shown with three lead ins 126, it will be appreciated that greater numbers of lead ins 126 may be used in various embodiments. For example, heater plate 116 may include at least three lead ins, at least four lead ins, at least five lead ins, at least six lead ins, at least 10 lead ins, at least 20 lead ins, or more. Lead ins 126 may be positioned at regular or irregular intervals about heating plate 116. In some embodiments, each lead in 126 may be formed from or otherwise include a ceramic or other dielectric material. In a particular embodiment, each lead in 126 may be formed from other otherwise include silicon nitride.

Heater plate 116 may include one or more standoffs 128 that may elevate a substrate above a top surface of heater plate 116. For example, each standoff 128 may be positioned at a position in which the respective standoff 128 protrudes upward from the surface of heater plate 116 radially inward of an outer periphery of a substrate centered on heater plate 116. For example, if the substrate has a diameter of 300 mm, each standoff 128 may be positioned within 150 mm of a center of heater plate 116. In some embodiments, each standoff 128 may be at a same radial distance from a center of heater plate 116, while in other embodiments one or more standoffs 128 may be at different radial positions. For example, as illustrated, heater plate 116 includes an annular array of standoffs 128 at one radial position and two additional standoffs 128 on opposing sides of a center of heater plate 116 at a second, more inward radial position. It will be appreciated that any arrangement of three or more standoffs 128 may be utilized that stably supports a substrate above heater plate 116. While shown with eight standoffs 128, it will be appreciated that other numbers of standoffs 128 may be used in various embodiments. For example, heater plate 116 may include at least three standoffs, at least four standoffs, at least five standoffs, at least six standoffs, at least 10 standoffs, at least 20 standoffs, or more. Standoffs 128 may be positioned at regular or irregular intervals about heater plate 116. In some embodiments, each standoff 128 may protrude above heater plate 116 by a smaller distance than each lead in 126, which may enable lead ins 126 to center a substrate with respect to heater plate 116 even when the substrate is seated atop standoffs 128. In some embodiments, a height or protrusion distance of each standoff 128 may be adjustable. For example, each standoff 128 may be coupled with an actuator (not shown) that may be used to raise and lower standoffs 128 with respect to heater plate 116. The actuator may include a shoulder bolt that includes standoff 128 on a top end of the shoulder bolt. Shims may be positioned under the shoulder bolt to adjust the protrusion height of standoff 128. In some embodiments, the actuator may include a motorized linear actuator that may control a protrusion height of standoff 128. In some embodiments, each standoff 128 may be formed from a crystalline material, such as sapphire, although other materials (including electrically conductive materials) are possible in various embodiments.

Heater plate 116 may define one or more backside gas ports 130. Each backside gas port 130 may be fluidly coupled with at least one gas source, which may be used to flow a gas to a backside of the substrate. For example, an inert gas, such as helium, may be flowed to the backside of the substrate through backside gas ports 130 to help thermally couple the substrate with heater plate 116. Any number of backside gas ports 130 may be included on heater plate 116. For example, heater plate 116 may include one or more backside gas ports, two or more backside gas ports, three or more backside gas ports, four or more backside gas ports, five or more backside gas ports, six or more backside gas ports, or more. Backside gas ports 130 may be disposed at any location and in any arrangement on heater plate 116. In a particular embodiment, heater plate 116 may define a single backside gas port 130, which may be centered or approximately centered (e.g., within an inner 15% of heater plate 116, within an inner 10% of heater plate 116, within an inner 5% of heater plate 116, within an inner 1% of heater plate 116, etc.) on heater plate 116. The use of a single, centrally location backside gas port 130 may reduce the purge time of backside gas ports 130 and may simplify the design of heater plate 116.

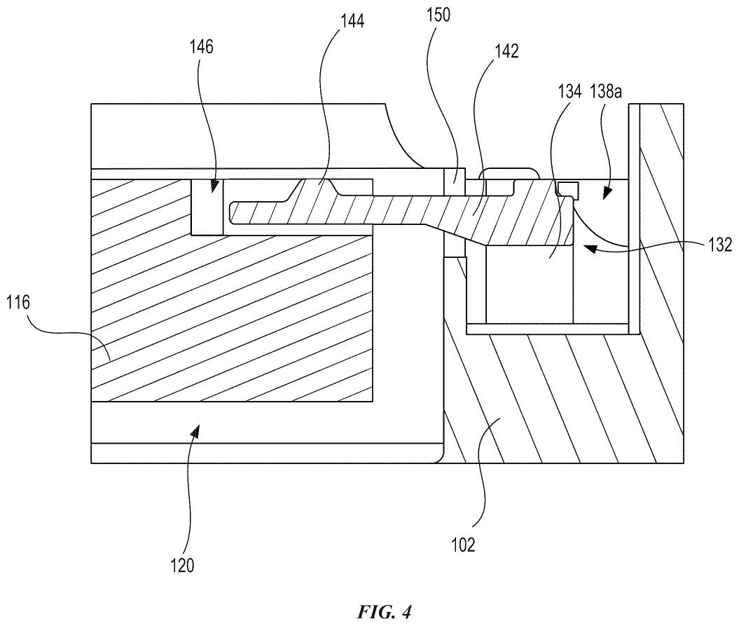

Chamber 100 may include a transfer hoop 132, which may be positioned within chamber interior 104. Transfer hoop 132 may include an annular or arcuate hoop body 134 that may be translated between a heating position and a cooling position. In the heating position, a central axis of hoop body 134 may be axially aligned with a central axis of heater plate 116. In the cooling position, the central axis of hoop body 134 may be axially aligned with a central axis of cooling plate 108. To facilitate such translation, hoop body 134 may be coupled with an actuator 136 that may rotate and/or otherwise move transfer hoop 134 between the heating position and the cooling position within chamber interior. Actuator 136 may be coupled with a motor controller 140 that controls operation of actuation of actuator 136. Motor controller 140 may be mounted on base 102, such as outside of chamber interior 104. Actuator 136 may be a rotational actuator, such as a belt and pulley actuator, a pneumatic actuator, a piston actuator, a vane actuator, a gear actuator, a hydraulic actuator, and/or other actuator. In some embodiments, actuator 136 may also be configured to vertically translate transfer hoop 134 within chamber interior 104. For example, actuator 136 may raise transfer hoop 134 above a top surface of heater plate 116 and cooling plate 108 to transfer substrates between the plates. During annealing operations, actuator 136 may lower transfer hoop 134 below a surface top surface of heater plate 116 and cooling plate 108. To accommodate the lower position of transfer hoop 134, base 102 may define one or more transfer hoop recesses 138. For example, base 102 may define one transfer hoop recess 138a about at least a portion of heater plate 116 and/or one transfer hoop recess 138b about at least a portion of cooling plate 108. Each transfer hoop recess 138 may provide clearance for transfer hoop 134 to be lowered and recessed relative to heater plate 116 and/or cooling plate 108 as best shown in FIG. 4. Each transfer hoop recess 138 may be sized and shaped to closely match a size and shape of transfer hoop 134, which may help encourage temperature uniformity about the respective plate. For example, in some embodiments, vertical and/or horizontal walls defining each transfer hoop recess 138 may be spaced apart from transfer hoop 134 (when transfer hoop 134 is disposed within the respective transfer hoop recess 138) of mm, no greater than 2 mm, no greater than 1 mm, no greater than 0.75 mm, no greater than 0.5 mm, no greater than 0.25 mm, or less (but not touching). Such close proximity may increase thermal transfer between transfer hoop 132 and base 102 (which defines transfer hoop recesses 138) and may help keep transfer hoop 132 cooler when in proximity to heater plate 116. In some embodiments, each transfer hoop recess 138 may have a sufficient depth such that transfer hoop 132 may be fully recessed relative to the top surface of the respective plate about which transfer hoop 132 is positioned. In some embodiments, the depth of each transfer hoop recess 138 may enable transfer hoop 132 to be fully recessed without touching a bottom of transfer hoop recesses 138.

Each transfer hoop 132 may include a number of substrate-engaging fingers 142 that may extend radially inward into an interior of hoop body 134. Substrate-engaging fingers 142 may be configured to engage a bottom surface and/or peripheral edge of a substrate to lift and lower the substrate during transfer of the substrate between cooling plate 108 and heater plate 116. While shown with three substrate-engaging fingers 142, it will be appreciated that greater numbers of substrate-engaging fingers 142 may be used in various embodiments. For example, transfer hoop 132 may include at least three substrate-engaging fingers, at least four substrate-engaging fingers, at least five substrate-engaging fingers, at least six substrate-engaging fingers, at least 10 substrate-engaging fingers, at least 20 substrate-engaging fingers, or more. Substrate-engaging fingers 142 may be positioned at regular or irregular intervals about transfer hoop 132. In some embodiments, each substrate-engaging fingers 142 may be formed from or otherwise include a crystalline material, such as opaque quartz, or other material with low thermal conductance. Such materials may help isolate substrates supported atop substrate-engaging fingers from heat from transfer hoop 132, which may be warmed to some degree due to its proximity to heater plate 116.

In some embodiments, each substrate-engaging finger 142 may include an upward facing protrusion 144 that is positioned to center a substrate within transfer hoop 132. For example, upward protrusions 144 may be formed on a medial portion of each substrate-engaging finger 142 and may be positioned such that a radially inward surface of each protrusion 144 is protrudes upward from a top surface of substrate-engaging finger 142 just outside (e.g., less than 2 mm, less than 1 mm, less than 0.5 mm, less than 0.25 mm, less than 0.1 mm, or less) of an outer periphery of a substrate centered on transfer hoop 132. For example, if the substrate has a diameter of 300 mm, each protrusion 144 may be positioned at between or about 150 mm and 152 mm from a center of transfer hoop 132. Such positioning may help ensure that a substrate supported atop substrate-engaging fingers 142 may be centered with respect to transfer hoop 132, as the substrate may be maintained radially inward of protrusions 144, with protrusions 144 being in contact and/or close proximity with a peripheral edge of the substrate to prevent the substrate from laterally shifting within transfer hoop 132.

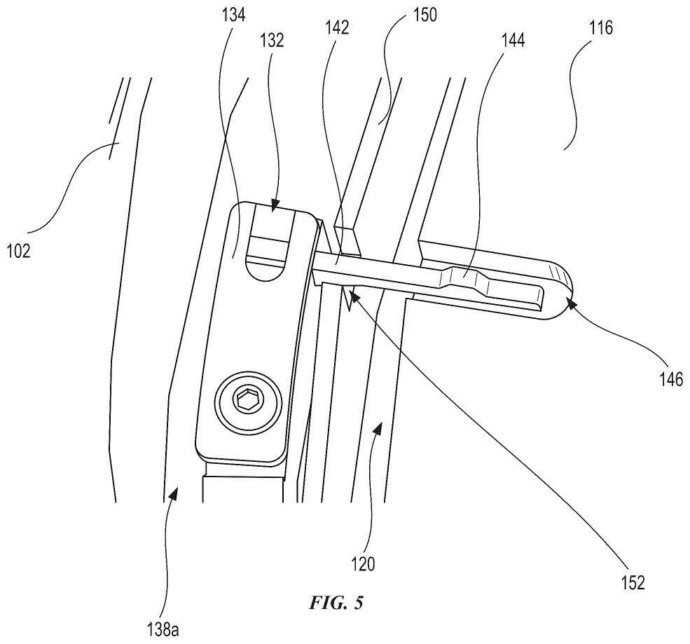

To accommodate substrate-engaging fingers 142 when transfer hoop 132 is in a lowered position (e.g., recessed relative to top surfaces of heater plate 116 and/or cooling plate 108), heater plate 116 and/or cooling plate 108 may define a number of recesses 146 that extend partially through a thickness of the respective plate, as best shown in FIG. 5. Each recess 146 may be aligned with a respective one of the substrate-engaging fingers 142 when transfer hoop 132 is positioned about a given plate. In some embodiments, a number and angular spacing of recesses 146 may match that of substrate-engaging fingers 142 such that each recess 146 receives one substrate-engaging finger 142 when transfer hoop 132 is positioned about the respective plate. In some embodiments, each recess 146 may be sized and shaped to closely match a size and shape of a substrate-engaging finger 142, which may help reduce temperature uniformity effects of the recesses 146. For example, in some embodiments, vertical and/or horizontal walls defining each recess 146 may be spaced apart from a substrate-engaging finger 142 of transfer hoop 132 (when the substrate-engaging finger 142 is disposed within the respective recess 146) by no greater than 2 mm, no greater than 1 mm, no greater than 0.75 mm, no greater than 0.5 mm, no greater than 0.25 mm, or less (but not touching). In some embodiments, each recess 146 may have a sufficient depth such that substrate-engaging fingers 142 may be fully recessed relative to the top surface of heater plate 116. In some embodiments, the depth of each recess 146 may enable substrate-engaging fingers 142 to be fully recessed without touching a bottom of recesses 146. In some embodiments, each lead in 110 and/or 126 may be positioned proximate (e.g., within 25 mm, within 20 mm, within 15 mm, within 10 mm, within 5 mm, etc.) of one of the recesses 146, which may help improve tolerances related to positioning the substrate atop a given plate.

In some embodiments, chamber interior 104 may be generally stadium shaped to accommodate heater plate 116 and cooling plate 108 being positioned side by side. Chamber interior 104 may take other shapes in some embodiments. In the illustrated embodiment, chamber interior 104 is arcuate or lima bean shaped as shown in FIG. 1. For example, an additional wedge-shaped region 148 is disposed between heater plate 116 and cooling plate 108. Wedge-shaped region 148 may be provided to accommodate movement of transfer hoop 132 between the heating position and the cooling position. For example, actuator 136 may be configured to move transfer hoop 132 between the heating position and the cooling position using a sweeping, arcuate motion. Wedge-shaped region 148 may provide sufficient clearance for transfer hoop 132 to move along an arcuate path within chamber interior 104.

In some embodiments, such as those in which chamber 100 is used in high temperature (e.g., at or in excess of 300° C., 350° C., 400° C., or more) anneal processes, base 102 may include a heat shield 150 that may extend about some or all of heater plate 116. Heat shield 150 may be formed integrally with base 102 or may be a separate component in some embodiments. Heat shield 150 may extend between and separate heater plate 116 and transfer hoop recess 138a. Heat shield 150 may be designed to shield transfer hoop 132 and a substrate seated thereon from the high temperatures of heating plate 116, as heat from heating plate 116 may otherwise warm up a portion of transfer hoop 132 and/or the substrate and cause localized temperature uniformity issues at areas proximate heater plate 116. In some embodiments, heat shield 150 may take the form of a fin or other protrusion that extends upward from base 102 at a position proximate to a peripheral edge of heater plate 116. For example, heat shield 150 may be positioned between or about 0.5 mm and 10 mm from the peripheral edge of heater plate 116, between or about 1 mm and 5 mm from the peripheral edge of heater plate 116, or between or about 2 mm and 4 mm from the peripheral edge of heater plate 116. In some embodiments, a top surface of heat shield 150 may be coplanar with a top surface of heater plate 116, while in other embodiments a top surface of heat shield 150 may be above or below the top surface of heater plate 116, such as within 10 mm, within 5 mm, within 3 mm, within 1 mm, or less above or below the top surface of heater plate 116. In some embodiments, a thickness of heat shield 150 may between or about 1 mm and 5 mm, or between or about 1.5 mm and 3 mm, although other thicknesses are possible in various embodiments.

In some embodiments, heat shield 150 may define a plurality of slits 152 that enable substrate-engaging fingers 142 to protrude radially inward of heat shield 150. As shown in FIG. 4. each slit 152 may be aligned with a respective one of the substrate-engaging fingers 142 when transfer hoop 132 is positioned about heater plate 116. In some embodiments, a number and angular spacing of slits 152 may match that of substrate-engaging fingers 142 such that each slit 152 receives one substrate-engaging finger 142 when transfer hoop 132 is positioned about heater plate 116. In some embodiments, each slit 152 may be sized and shaped to closely match a size and shape of a substrate-engaging finger 142, which may help reduce temperature uniformity effects of the slits 152 on transfer hoop 132. For example, in some embodiments, vertical and/or horizontal walls defining each slit 152 may be spaced apart from a substrate-engaging finger 142 of transfer hoop 132 (when the substrate-engaging finger 142 is disposed within the respective slit 152) of no greater than 2 mm, no greater than 1 mm, no greater than 0.75 mm, no greater than 0.5 mm, no greater than 0.25 mm, or less. In some embodiments, each slit 152 may have a sufficient depth such that substrate-engaging fingers 142 may be fully recessed relative to the top surface of heater plate 116. In some embodiments, the depth of each slit 152 may enable substrate-engaging fingers 142 to be fully recessed without touching a bottom of slits 152.

Chamber 100 may include one or more exhaust ports 154 that enable gases within chamber interior 104 to be evacuated from chamber interior 104 before, during, and/or after annealing operations. Exhaust ports 154 may be positioned to lessen effects of gases heated by heater plate 116 from sweeping over a substrate when the substrate is positioned over cooling plate 108. For example, base 102 may define and/or otherwise include one or more exhaust ports 154a that are positioned beneath heater plate 116, as shown in FIG. 3. Exhaust ports 154a may be positioned to draw gases warmed by heater plate 116 out of chamber interior 104 downward about the peripheral edge of heater plate 116, into recess 120 below heater plate 116 and out of chamber interior 104. Any number of exhaust ports 154a may be provided beneath heater plate 116. For example, base 102 may include one or more exhaust ports 154a, two or more exhaust ports 154a, three or more exhaust ports 154a, four or more exhaust ports 154a, five or more exhaust ports 154a, six or more exhaust ports 154a, or more. Chamber 100 may include additional exhaust ports 154b proximate cooling plate 108 to further evacuate gases from chamber interior 104 as shown in FIG. 2. In some embodiments, chamber 100 may include one or more exhaust ports 154b that are proximate transfer port 106. By segregating exhaust ports 154 (e.g., separate exhaust ports 154a proximate/under heater plate 116—and exhaust ports 154b near cooling plate 108/transfer port 106 may enable warmed purge gases flowing near heater plate 116 to be locally evacuated without warming cooling plate 108, while enabling cooled purge gases flowing near cooling plate 108 to be locally evacuated without cooling heater plate 116. Thus, such exhaust configurations may improve the thermal isolation between heater plate 116 and cooling plate 108. Additionally, such exhaust configurations may ensure that any particles that are released as the substrate is heated on heater plate 116 do not flow over cooling plate 108.

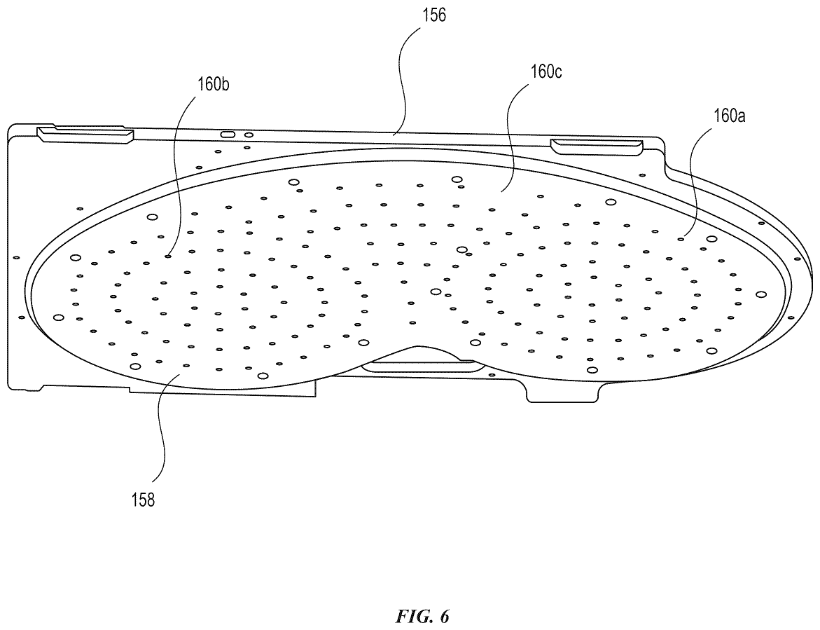

As shown in FIG. 6, chamber 100 may include a lid 156 that is coupled with base 102. Lid 156 may extend over and enclose chamber interior 104. In some embodiments, lid 156 may be secured with base 102 using a number of fasteners, such as bolts or screws. Lid 156 may include an inner surface 158 that faces chamber interior 104. In some embodiments, inner surface 158 may be designed to reduce the reflection of heat, which may prevent heat radiating from heater plate 116 from being reflected onto cooling plate 108 and/or a substrate supported by cooling plate 108. To reduce the heat reflection of inner surface 158, inner surface 158 may be finished and/or treated with a dark surface, such as by anodizing inner surface 158 to have a black or other dark color and/or applying a black or otherwise dark film on inner surface 158. In some embodiments, inner surface 158 may have an emissivity texture, such as a roughened texture, that may reduce the ability of inner surface 158 to reflect heat. In some embodiments, inner surface 158 may have a thermal emissivity of at least 0.7, at least 0.75, at least 0.8, at least 0.85, at least 0.9, at least 0.95, or greater.

Lid 156 may define a number of gas distribution apertures 160 through inner surface 158. Gas distribution apertures 160 may be fluidly coupled with one or more gas sources (not shown), which may be coupled with chamber 100 and/or may be removed from chamber 100. Gas distribution apertures 160 may be designed to deliver one or more gases, such as an inert gas (e.g., N2) or a forming gas, to chamber interior 104 to facilitate annealing processes. Gas distribution apertures 160 may extend over heater plate 116, cooling plate 108, and/or wedge-shaped region 148. For example, in the illustrated embodiment, the gas distribution apertures 160 include a first set of gas distribution apertures 160a that are disposed above heater plate 116, a second set of gas distribution apertures 160b that are disposed above cooling plate 108, and a third set of gas distribution apertures 160c that are disposed above wedge-shaped region 148. In some embodiments, gas distribution apertures 160a may be arranged as a first set of concentric rings over heater plate 116. The concentric rings may be circular, hexagonal, and/or may take other shapes and may be concentric with a center of heater plate 116 in some embodiments. Gas distribution apertures 160b may be arranged as a second set of concentric rings over cooling plate 108. The concentric rings may be circular, hexagonal, and/or may take other shapes and may be concentric with a center of cooling plate 108 in some embodiments. Gas distribution apertures 160c may be arranged in a set of concentric arcs. The concentric rings may be circular, hexagonal, and/or may take other shapes and may be concentric with a point that falls on a line halfway between cooling plate 108 and heater plate 116 in some embodiments. Thus, in some embodiments, the first set of concentric rings, the second set of concentric rings, and the set of concentric arcs may each have different center points. Lid 156 may define a plenum (not shown) that is positioned above gas distribution apertures 160. Gas may be flowed into the plenum and through gas distribution apertures 160 into chamber interior 104. In some embodiments, the plenum may be formed from joining a diffuser plate (such as a lower diffuser plate) to lid 156. In some embodiments, plenum may be formed from bottom surfaces of lid 156 and top surfaces of the diffuser plate.

While illustrated with gas distribution apertures 160 being arranged in set of concentric arcs and/or rings, it will be appreciated that gas distribution apertures 160 may be arranged in other manners in various embodiments. Lid 156 may include any number of gas distribution apertures 160. For example, lid 156 may include at least 25 gas distribution apertures, at least 50 gas distribution apertures, at least 100 gas distribution apertures, at least 250 gas distribution apertures, at least 500 gas distribution apertures, at least 1,000 gas distribution apertures, or more.

By positioning gas distribution apertures 160 over substantially all of chamber interior 104 (e.g., over plate 116, cooling plate 108, and wedge-shaped region 148), lid 156 may provide better distribution of purge gas throughout an entirety of chamber interior 104 and may better evacuate any oxygen from within the chamber environment prior to beginning annealing operations. Additionally, such gas distribution may result in a heated substrate having a temperature that more closely matches that of heater plate 116.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of 20% or ±10%, +5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of 20% or +10%, +5%, or +0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. An anneal chamber, comprising:
a base that defines a chamber interior, wherein the base comprises a cooling plate within the chamber interior, wherein the base and the cooling plate are integral with one another;
a lid that is coupled with the base;
a heater plate mounted in the chamber interior alongside the cooling plate;
a transfer hoop movably coupled within the chamber interior, wherein:
the base defines a first transfer hoop recess about at least a portion of the heater plate; and
the base defines a second transfer hoop recess about at least a portion of the cooling plate.

2. The anneal chamber of claim 1, wherein:
the base comprises a heat shield that extends between the heater plate and the first transfer hoop.

3. The anneal chamber of claim 1, wherein:
the transfer hoop comprises a plurality of substrate-engaging fingers;
the heater plate defines a plurality of recesses that extend partially through a thickness of the heater plate; and
each of the plurality of recesses is aligned with a respective one of the plurality of substrate-engaging fingers.

4. The anneal chamber of claim 1, wherein:
the transfer hoop comprises a plurality of substrate-engaging fingers;
the cooling plate defines a plurality of recesses that extend partially through a thickness of the cooling plate; and
each of the plurality of recesses is aligned with a respective one of the plurality of substrate-engaging fingers.

5. The anneal chamber of claim 1, wherein:
the lid defines a first plurality of gas distribution apertures positioned above the heater plate; and
the lid defines a second plurality of gas distribution apertures positioned above the cooling plate.

6. The anneal chamber of claim 5, wherein:
the lid defines a third plurality of gas distribution apertures in a region disposed between the heater plate and the cooling plate.

7. The anneal chamber of claim 6, wherein:
the first plurality of gas distribution apertures are arranged in a first plurality of concentric rings;
the second plurality of gas distribution apertures are arranged in a second plurality of concentric rings; and
the third plurality of gas distribution apertures are arranged in a plurality of concentric arcs.

8. The anneal chamber of claim 7, wherein:
the first plurality of concentric rings, the second plurality of concentric rings, and the plurality of concentric arcs each have different center points.

9. The anneal chamber of claim 1, wherein:
each of the heater plate and the cooling plate defines a single backside gas port.

10. An anneal chamber, comprising:
a base that defines a chamber interior, wherein the base comprises a cooling plate within the chamber interior, wherein the base and the cooling plate are integral with one another;
a lid that is coupled with the base;
a heater plate mounted in the chamber interior alongside the cooling plate, wherein the heater plate comprises multiple heating zones;
a transfer hoop movably coupled within the chamber interior, wherein:
the base defines a first transfer hoop recess about at least a portion of the heater plate; and
the base defines a second transfer hoop recess about at least a portion of the cooling plate.

11. The anneal chamber of claim 10, wherein:
each of the heater plate and the cooling plate defines a plurality of standoffs that are configured to support a substrate at a position that is elevated relative to a top surface of the respective plate.

12. The anneal chamber of claim 11, wherein:
a height of the plurality of standoffs is adjustable relative to the top surface of the respective plate.

13. The anneal chamber of claim 10, wherein:
the base defines one or more exhaust ports that are disposed beneath the heater plate.

14. The anneal chamber of claim 10, wherein:
the lid comprises an anodized inner surface.

15. The anneal chamber of claim 10, wherein:
the transfer hoop comprises a plurality of substrate-engaging fingers; and
each of the substrate-engaging fingers comprises an upward facing protrusion that is positioned to center a substrate within the transfer hoop.

16. The anneal chamber of claim 15, wherein:
each of the plurality of substrate-engaging fingers comprises quartz.

17. An anneal chamber, comprising:
a base that defines a chamber interior, wherein the base comprises a cooling plate within the chamber interior, wherein the base and the cooling plate are integral with one another;
a heater plate mounted in the chamber interior alongside the cooling plate;
a lid that is coupled with the base, wherein the lid defines a plurality of gas distribution apertures that extend over the heater plate and the cooling plate; and
a transfer hoop movably coupled within the chamber interior.

18. The anneal chamber of claim 17, wherein:
the base defines a transfer port proximate the cooling plate.

19. The anneal chamber of claim 17, wherein:
the base comprises a heat shield that extends between the heater plate and the transfer hoop;
the transfer hoop comprises a plurality of substrate-engaging fingers; and
the heat shield defines a plurality of slits that enable the plurality of substrate-engaging fingers to protrude radially inward of the heat shield.

20. The anneal chamber of claim 17, wherein:
the heating plate comprises a circular heating zone and an annular heating zone that is disposed radially outward of the circular heating zone; and
the circular heating zone and the annular heating zone are independently controllable.
